(19) United States
(12) Patent Application Publication
(10) Pub. No.: US 2015/0333140 A1
(43) Pub. Date: Nov. 19, 2015

(54) SEMICONDUCTOR STRUCTURE AND METHOD OF FORMING THE SAME

(71) Applicant: Maxchip Electronics Corp., Hsinchu City (TW)

(72) Inventor: Kosuke Yoshida, Hsinchu City (TW)

(73) Assignee: Maxchip Electronics Corp., Hsinchu City (TW)

(21) Appl. No.: 14/277,809

(22) Filed: May 15, 2014

(51) Int. Cl. H01L 29/423; H01L 29/66; H01L 21/764; H01L 29/78

(52) U.S. Cl. CPC H01L 29/42364; H01L 29/7827; H01L 29/4236; H01L 29/66666; H01L 21/764

(57) ABSTRACT

A semiconductor structure is provided. An N-type epitaxial layer is disposed on an N-type substrate. The N-type epitaxial layer has at least one trench therein, wherein the trench has a straight sidewall. A first insulating layer is disposed on at least a portion of a surface of the trench. A silicon-containing layer is disposed in a lower portion of the trench and has at least one air gap therein. A first conductive layer is disposed in an upper portion of the trench. Two P-type well regions are disposed in the N-type epitaxial layer beside the trench. Two N-type source regions are respectively disposed in the P-type well regions beside the trench.

### BACKGROUND OF THE INVENTION

1. Field of Invention

The present invention relates to a semiconductor structure and a method of forming the same, and more particularly to a trench gate metal-oxide-semiconductor (MOS) structure and a method of forming the same.

2. Description of Related Art

A trench gate MOS structure has been widely applied in power switch devices, such as power supplies, rectifiers, low-voltage motor controllers, or so forth. In general, the trench gate MOS structure is often resorted to a design of vertical structure to enhance the device density. For example, drain terminal is formed on the back-side of a chip, and each source region and each gate are formed on the front-side of the chip. The drain regions of the transistors are connected in parallel so as to endure a considerable large current.

The working loss of the trench gate MOS structure may be divided into a switching loss and a conducting loss, wherein the switching loss caused by the input capacitance Cᵢₛₛ is going up as the operation frequency is increased. The input capacitance Cᵢₛₛ includes a gate-to-source capacitance C_{gs} and a gate-to-drain capacitance C_{gd}. Several practices are implemented to reduce the gate-to-drain capacitance and therefore the switching loss. One conventional practice is to form a trench gate with thick bottom oxide to lower the gate-to-drain capacitance. Another conventional practice is to form a shield gate below the gate to reduce the gate-to-drain capacitance. However, as the pitch of a device is shrunk down continuously, the above two practices face difficulties in creating a high aspect ratio trench, filling a material in the trench, etc.

### SUMMARY OF THE INVENTION

Accordingly, the present invention provides a semiconductor structure and a method of forming the same, in which a trench gate MOS structure is formed with an air gap bottom (AGB) below the gate thereof, so as to reduce the gate-to-drain capacitance and therefore the switching loss.

The present invention provides a semiconductor structure, which includes a substrate of a first conductivity type; an epitaxial layer of the first conductivity type disposed on the substrate and having at least one trench therein, wherein the trench has a straight sidewall; a first insulating layer disposed on at least a portion of a surface of the trench; a silicon-containing layer disposed in a lower portion of the trench and having at least one air gap therein; a first conductive layer disposed in an upper portion of the trench; two well regions of a second conductivity type disposed in the epitaxial layer beside the trench; and two source regions of the first conductivity type respectively disposed in the well regions beside the trench.

According to an embodiment of the present invention, the first insulating layer and the silicon-containing layer include the same or different materials.

According to an embodiment of the present invention, the silicon-containing layer includes silicon oxide, amorphous silicon, porous silica, fluorinated silicon oxide, silicon nitride, silicon oxynitride, polysilicon or a combination thereof.

According to an embodiment of the present invention, the first insulating layer covers an entire surface of the trench.

According to an embodiment of the present invention, the first insulating layer covers a surface of the lower portion of the trench.

According to an embodiment of the present invention, the semiconductor structure further includes a second insulating layer disposed between the first conductive layer and the epitaxial layer and between the first conductive layer and the silicon-containing layer; and an air space present between the silicon-containing layer and the second insulating layer and between the silicon-containing layer and the first insulating layer.

According to an embodiment of the present invention, the silicon-containing layer further has a plurality of air cracks therein.

According to an embodiment of the present invention, the semiconductor structure further includes a plurality of pillars of the second conductivity type separately disposed in the epitaxial layer.

According to an embodiment of the present invention, the semiconductor structure further includes a dielectric layer disposed on the epitaxial layer; a second conductive layer disposed on the dielectric layer and electrically connected to the source regions via two contact plugs; and two doped regions of the second conductivity type respectively disposed in the well regions and around bottoms of the contact plugs.

According to an embodiment of the present invention, the first conductivity type is N-type and the second conductivity type is P-type; or the first conductivity type is P-type and the second conductivity type is N-type.

The present invention further provides a method of forming a semiconductor device. An epitaxial layer of a first conductivity type is formed on a substrate of the first conductivity type. At least one trench is formed in the epitaxial layer, wherein the trench has a straight sidewall. A first insulating layer is formed at least on a portion of a surface of the trench. A silicon-containing layer is formed in a lower portion of the trench, wherein the silicon-containing layer has at least one air gap therein. A first conductive layer in an upper portion of the trench. Two well regions of a second conductivity type are formed in the epitaxial layer beside the trench. Two source regions of the first conductivity type are formed respectively in the well regions beside the trench.

According to an embodiment of the present invention, the step of forming the silicon-containing layer includes forming a silicon-containing material layer on the substrate filling the trench in a manner such that the air gap is simultaneously formed in the silicon-containing material layer; annealing the silicon-containing material layer; and removing a portion of the silicon-containing material layer.

According to an embodiment of the present invention, the silicon-containing material layer is formed by CVD, PVD or sputtering, and the annealing is performed at a temperature of about 1,000 to 1,200° C. for 10 to 180 minutes.

According to an embodiment of the present invention, the step of forming the silicon-containing layer includes forming a silicon-containing material layer on the substrate filling the trench; removing a portion of the silicon-containing material layer to form the silicon-containing layer; and annealing the silicon-containing layer in a manner such that the air gap is simultaneously formed in the silicon-containing layer.

According to an embodiment of the present invention, the silicon-containing material layer is formed by CVD, PVD or sputtering, and the annealing is performed at a temperature of 600 to 1,000° C. for 10 to 180 minutes.

According to an embodiment of the present invention, during the annealing, an air space is simultaneously formed between the first insulating layer and the silicon-containing layer and between the second insulating layer and the silicon-containing layer, and a plurality of air cracks are simultaneously formed in the silicon-containing layer.

According to an embodiment of the present invention, the first insulating layer and the silicon-containing layer include the same or different materials.

According to an embodiment of the present invention, the silicon-containing layer includes silicon oxide, amorphous silicon, porous silica, fluorinated silicon oxide, silicon nitride, silicon oxynitride, polysilicon or a combination thereof.

According to an embodiment of the present invention, after the step of forming the epitaxial layer and before the step of forming the trench, the method further includes forming a plurality of pillars of the second conductivity type separately in the epitaxial layer.

According to an embodiment of the present invention, the method further includes forming a dielectric layer on the epitaxial layer; forming at least two openings penetrating through the dielectric layer and the source regions and extending into a portion of the well regions; forming two doped regions of the second conductivity type respectively in the well regions around bottoms of the openings; forming two contact plugs respectively in the openings; and forming a second conductive layer on the dielectric layer, wherein the second conductive layer is electrically connected to the source regions via the contact plugs.

Based on the foregoing, in the semiconductor structure of the invention, an air gap bottom is provided below the gate, so the gate-to-drain capacitance and therefore the switching loss can be effectively reduced. Besides, a super junction structure is further provided in the epitaxial layer, so as to make the structure capable of having characteristics of high breakdown voltage and low impedance.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are schematic cross-sectional views of a method of forming a semiconductor structure according to a first embodiment of the present invention.

FIG. 2A to FIG. 2E are schematic cross-sectional views of a method of forming a semiconductor structure according to a second embodiment of the present invention.

FIG. 3A to FIG. 3B are schematic cross-sectional views of a method of forming a semiconductor structure according to a third embodiment of the present invention.

FIG. 4A to FIG. 4B are schematic cross-sectional views of a method of forming a semiconductor structure according to a fourth embodiment of the present invention.

### DESCRIPTION OF EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

### First Embodiment

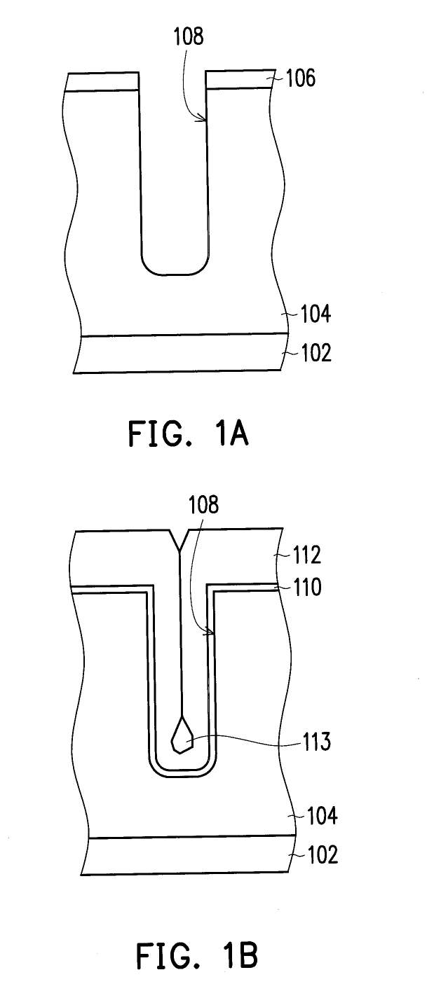

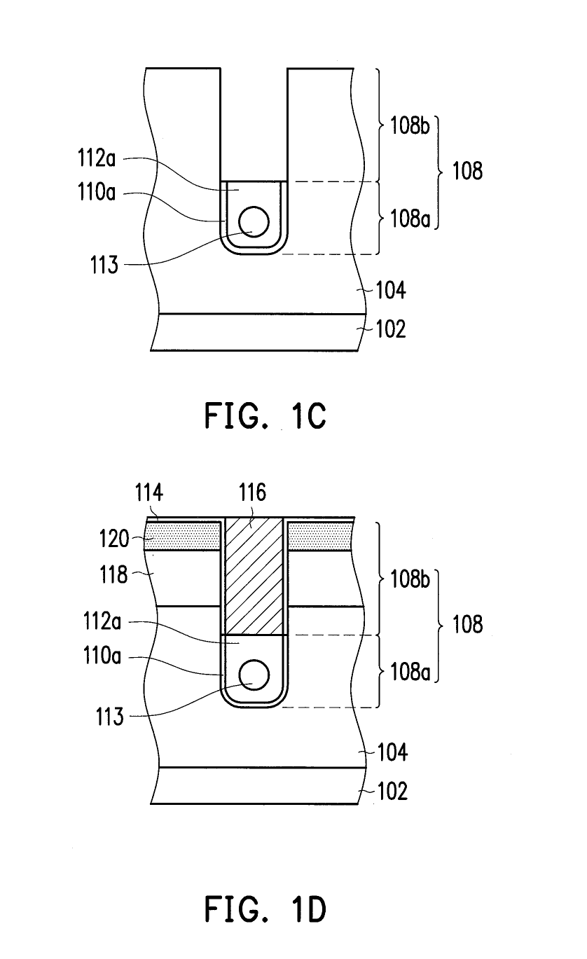

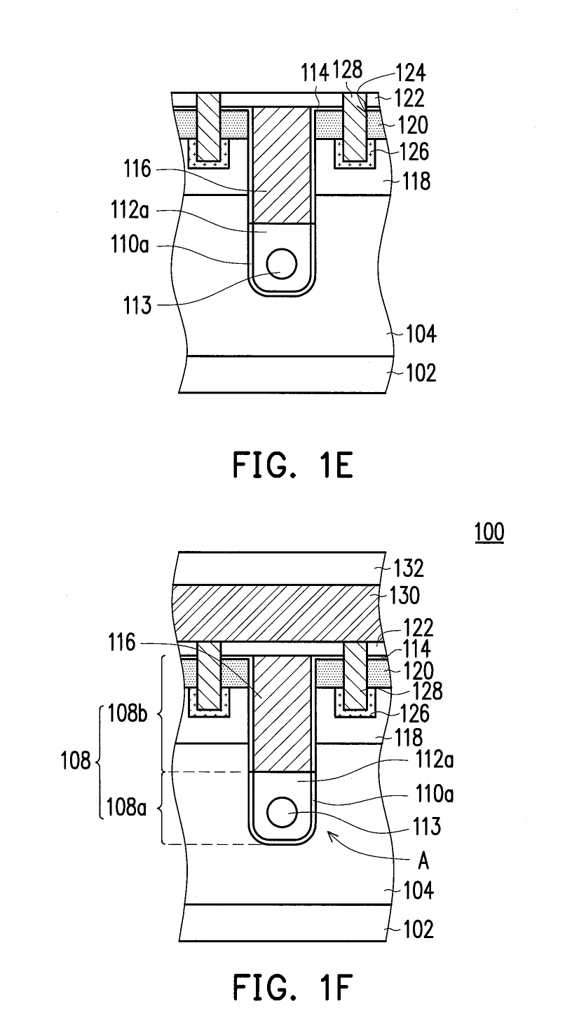

FIG. 1A to FIG. 1F are schematic cross-sectional views of a method of forming a semiconductor structure according to a first embodiment of the present invention.

Referring to FIG. 1A, an epitaxial layer 104 of a first conductivity type is formed on a substrate 102 of the first conductivity type. The substrate 102 can be an N-type heavily doped (N⁺) silicon substrate that can be used as a drain of a trench gate MOS structure. The epitaxial layer 104 can be an N-type lightly doped (N⁻) epitaxial layer, and the forming method thereof includes performing an epitaxy growth process.

Thereafter, a patterned mask layer 106 is formed on the epitaxial layer 104. The patterned mask layer 106 includes silicon oxide, silicon nitride, silicon oxynitride or a combination thereof, and the forming method thereof includes performing a chemical vapour deposition (CVD) process. In this embodiment, the patterned mask layer 106 can be a single material layer made of silicon oxide, as illustrated in FIG. 1A. In another embodiment (not shown), the patterned mask layer 106 can be a multi-layer structure including different materials. Then, an etching process is performed by using the patterned mask layer 106 as a mask, so as to remove a portion of the epitaxial layer 104, and therefore form at least one trench 108 in the epitaxial layer 104. The trench 108 has a straight sidewall. In an embodiment, the trench 108 has a vertical sidewall, as illustrated in FIG. 1A. In another embodiment (not shown), the trench 108 can have a tilted sidewall; that is, the trench 108 is formed with wide top and narrow bottom. Besides, the trench 108 can have a rounded or square corner. Afterwards, the patterned mask layer 106 is removed.

Referring to FIG. 1B, an insulating layer 110 is formed on the surfaces of the trench 108 and the epitaxial layer 104. The insulating layer 110 includes silicon oxide, and the forming method thereof includes performing a thermal oxidation process or a deposition process (e.g. CVD).

Thereafter, a silicon-containing material layer 112 is formed on the substrate 102 filling the trench 108. In an embodiment, the silicon-containing material layer 112 and the insulating layer 110 can include the same material. For example, the silicon-containing material layer 112 can include silicon oxide. Besides, the silicon-containing material layer 112 can be formed in a manner such that at least one air gap 113 is formed therein. In other words, the silicon-containing material layer 112 can be formed by a process with poor step coverage, such as CVD, physical vapour deposition (PVD) or sputtering. Such poor step coverage results from different deposition rates in different parts of the trench 108, and thus, one or more voids or air gaps 113 are easily formed during the formation of the silicon-containing material layer 112. Thereafter, the silicon-containing material layer 112 is annealed (for viscous flow) at a temperature of about 1,000 to 1,200° C. for 10 to 180 minutes, so as to stabilize the contact interface of the silicon-containing material layer 112.

Referring to FIG. 1C, a portion of the silicon-containing material layer 112 is removed, and thus, a silicon-containing layer 112a is formed in the lower portion 108a of the trench 108. The removing step includes performing an etching back process. In an embodiment, a portion of the insulating layer 110 can be simultaneously removed during the partial removing of the silicon-containing material layer 112, and thus, an insulating layer 110a is formed between the silicon-containing layer 112a and the epitaxial layer 104.

Referring to FIG. 1D, an insulating layer 114 is formed on the surface of the epitaxial layer 104 and on the sidewall of the upper portion 108b of the trench 108. The insulating layer 114 includes silicon oxide, and the forming method thereof includes performing a thermal oxidation process.

Thereafter, a conductive layer 116 is formed in the upper portion 108b of the trench 108. The conductive layer 116 includes doped polysilicon. In the case that doped polysilicon is adopted, the conductive layer 116 can include a dopant type (e.g. N-type dopant) the same as that of the source regions 120. The method of forming the conductive layer 116 includes forming a conductive material layer (not shown) on the substrate 102 filling the trench 108. The conductive material layer outside the trench 108 is removed by an etching back process or a chemical mechanical polishing (CMP) process.

Afterwards, two well regions 118 (or called body well regions) of a second conductivity type are formed in the epitaxial layer 104 beside the trench 108. Specifically, the well regions 118 are located beside the upper portion 108b of the trench 108, and the bottom surface of the well regions 118 are higher than the interface between the conductive layer 116 and the silicon-containing layer 112a. The well regions 118 can be P⁻ doped regions. The method of forming the well regions 118 include performing a first blanket implant process.

Thereafter, two source regions 120 of the first conductivity type are respectively formed in the well regions 118 beside the trench 108. The source regions 120 can be N⁺ doped regions The method of forming the source regions 120 include performing a second blanket implant process. Besides, the doping depths and doping concentrations of the first and second blanket implant processes have been calculated in advance, so that the electrical properties of the conductive layer 116 are not affected much although the conductive layer 116 is simultaneously doped during the first and second blanket implant processes. Since the well regions 118 and source regions 120 are respectively formed through a blanket implant process, no additional photomask is required and the process cost can be further reduced.

Referring to FIG. 1E, a dielectric layer 122 is formed on the epitaxial layer 104. The dielectric layer 122 includes silicon oxide, borophosphosilicate glass (BPSG), phosphosilicate glass (PSG), fluorosilicate glass (FSG), or undoped silicon glass (USG), and the forming method thereof includes performing a CVD process. Besides, the dielectric layer 122 has at least two openings 124 formed therein. The method of forming the openings 124 includes performing photolithography and etching processes.

Thereafter, using the dielectric layer 122 as a mask, an etching process is performed to deepen the openings 124, so that the openings 124 penetrate through the source regions 120 and extend into a portion of the well regions 118.

Afterwards, two doped regions 126 of the second conductivity type are formed in the well regions 118 around the bottoms of the openings 124. The doped regions 126 can be P⁺ doped regions. The method of forming the doped regions 126 includes performing an ion implant process and a subsequent driven-in process. Since the ion implant process uses the dielectric layer 122 as the mask, the process can be regarded as a self-aligned process. Each doped region 126 covers the entire bottom and a portion of sidewall of the corresponding opening 124.

Referring to FIG. 1F, two contact plugs 128 are respectively formed in the openings 124. The method of forming the contact plugs 128 includes forming a contact material layer (not shown) on the substrate 100 filling the openings 124. In an embodiment, the contact material layer can be a multi-layer structure including a barrier layer and a metal layer. The barrier layer includes titanium (Ti), titanium nitride (TiN), tantalum (Ta), tantalum nitride (TaN) or a combination thereof and can be formed through sputtering. The metal layer includes tungsten (W) and can be formed through CVD. Thereafter, the contact material layer outside the openings 124 are removed through etching back or CMP.

Then, a conductive layer 130 is then formed on the dielectric layer 122. The conductive layer 130 includes aluminium (Al), and the forming method thereof includes performing a deposition process (e.g. CVD) or a sputtering process. The conductive layer 130 is electrically connected to the source regions 120 via the contact plugs 128. Afterwards, a passivation layer or a cover 132 is formed on the conductive layer 130. The cover 132 includes silicon oxide, silicon nitride, silicon oxynitride or a combination thereof, and the forming method thereof includes performing a CVD process. The fabrication of the semiconductor structure 100 is thus completed.

The semiconductor structure of the invention is explained with reference to FIG. 1F. As shown in FIG. 1F, the semiconductor structure 100 includes a substrate 102 of a first conductivity type, an epitaxial layer 104 of the first conductivity type, insulating layers 110a and 114, a silicon-containing layer 112a, a conductive layer 116, two well regions 118 of a second conductivity type and two source regions 120 of the first conductivity type. The epitaxial layer 104 is disposed on the substrate 102 and has at least one trench 108 therein. The trench 108 has a straight sidewall. That is, the sidewall of the lower portion 108a is aligned with the sidewall of the upper portion 108b of the trench 108. The insulating layers 110a and 114 cover the entire surface of the trench 108. Specifically, the insulating layer 110a is disposed on the surface of the lower portion 108a of the trench 108, and the insulating layer 114 is disposed on the surface of the upper portion 108b of the trench 108. The silicon-containing layer 112a is disposed in the lower portion 108a of the trench 108 and has at least one air gap 113 therein.

In addition, the insulating layers 110a and 114 and the silicon-containing layer 112a include the same material (e.g. silicon oxide). The conductive layer 116 is disposed in the upper portion 108b of the trench 108. The well regions 118 are disposed in the epitaxial layer 104 beside the trench 108. The source regions 120 are respectively disposed in the well regions 120.

The semiconductor structure 100 further includes a dielectric layer 122, a conductive layer 130 and two doped regions 126 of the second conductivity type. The dielectric layer 122 is disposed on the epitaxial layer 104. The conductive layer 130 is disposed on the dielectric layer 122 and electrically connected to the source regions 120 via two contact plugs 128. The doped regions 126 are respectively disposed in the well regions 118 and around bottoms of the contact plugs 128, so as to effectively reduce the ohmic resistance of the contact plugs 128.

In the semiconductor structure 100 of FIG. 1F, the insulating layer 114 is used as a gate insulating layer and the conductive layer 116 is used as a gate. It is noted that the thick insulating layer 110a below the conductive layer 116 has an air gap 113 therein, so the gate-to-drain capacitance can be significantly reduced. Such thick bottom with at least one air gap therein can be referred to as an air gap bottom (AGB). Specifically, the dielectric constant of air (about 1) is much less than the dielectric constant of silicon oxide (about 3.9), so the equivalent dielectric constant in area A can be greatly decreased, thereby significantly reducing the gate-to-drain capacitance of the trench gate MOS structure.

### Second Embodiment

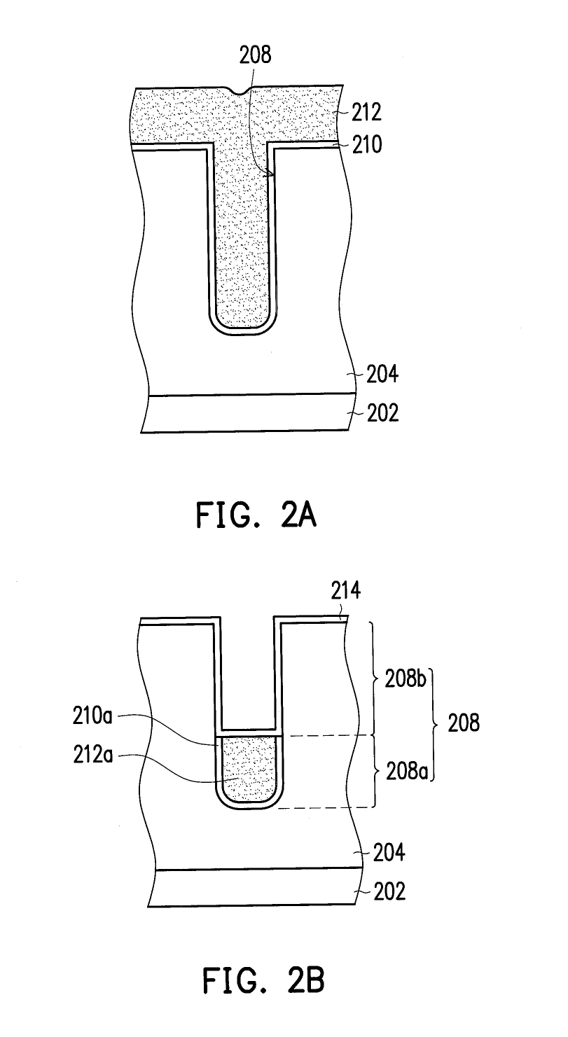

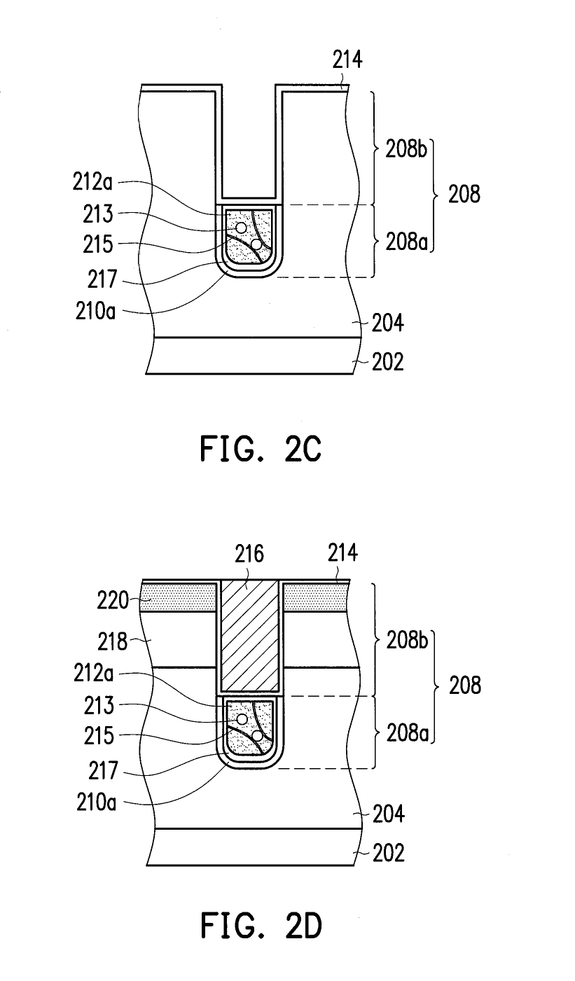

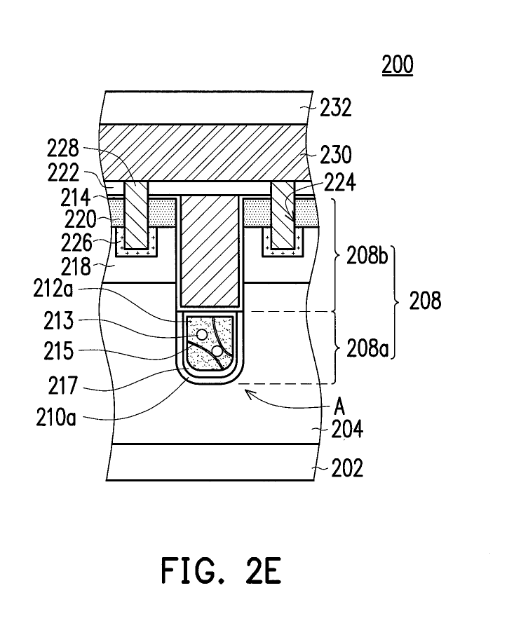

FIG. 2A to FIG. 2E are schematic cross-sectional views of a method of forming a semiconductor structure according to a second embodiment of the present invention.

Referring to FIG. 2A, an epitaxial layer 204 of a first conductivity type is formed on a substrate 202 of the first conductivity type. The substrate 202 can be an N-type heavily doped (N⁺) silicon substrate that can be used as a drain of a trench gate MOS structure. The epitaxial layer 204 can be an N-type lightly doped (N⁻) epitaxial layer, and the forming method thereof includes performing an epitaxy growth process. The epitaxial layer 204 has at least one trench 208 formed therein. Besides, the trench 208 has a straight sidewall.

Thereafter, an insulating layer 210 is formed on the surfaces of the trench 208 and the epitaxial layer 204. The insulating layer 210 includes silicon oxide, and the forming method thereof includes performing a thermal oxidation process or a deposition process (e.g. CVD).

Afterwards, a silicon-containing material layer 212 is formed on the substrate 202 filling the trench 208. In an embodiment, the silicon-containing material layer 212 and the insulating layer 210 can include different materials. For example, the silicon-containing material layer 212 includes amorphous silicon. The silicon-containing material layer 212 can be formed by a process, such as CVD, physical vapour deposition (PVD), or sputtering.

Referring to FIG. 2B, a portion of the silicon-containing material layer 212 is removed, and thus, a silicon-containing layer 212a is formed in the lower portion 208a of the trench 208. The removing step includes performing an etching back process. Thereafter, the insulating layer 210 not covered by the silicon-containing layer 212a is removed by an etching process, and thus, an insulating layer 210a is formed between the silicon-containing layer 212a and the epitaxial layer 204. Afterwards, an insulating layer 214 is formed on the surface of the epitaxial layer 204 and on the sidewall of the upper portion 208b of the trench 208. The insulating layer 214 includes silicon oxide, and the forming method thereof includes performing a thermal oxidation process, deposition process or a combination thereof.

Referring to FIG. 2C, the silicon-containing layer 212a is annealed in a manner such that at least air gap 213 is simultaneously formed in the silicon-containing layer 212a. Specifically, the annealing shrinks the silicon-containing layer 212a, so that a plurality of air gaps 213 and air cracks 215 are generated within the silicon-containing layer 212a. Moreover, due to the volume reduction or size shrinking of the silicon-containing layer 212a, an air space 217 is simultaneously formed between the silicon-containing layer 212a and each of the insulating layer 214 and the insulating layer 210 during the annealing step. The annealing step is performed at a temperature of about 600 to 1,000° C. for 10 to 180 minutes.

The said embodiment in which the silicon-containing layer 212a is made of amorphous silicon is provided for illustration purposes, and is not construed as limiting the present invention. It is appreciated by people having ordinary skill in the art that any material can be applied to this embodiment as long as it can shrink when heated. In other words, a heat-shrinkable material may be suitable because it shrinks and generates voids, air gaps and/or cracks therein and/or an air space therearound when it is subjected to an annealing or a heating treatment.

Referring to FIG. 2D to FIG. 2E, the steps similar to those described in FIG. 1D to FIG. 1F are performed, so as to form a semiconductor structure 200. Specifically, a conductive layer 216 is formed in the upper portion 208b of the trench 208. Two well regions 218 (or called body well regions) of a second conductivity type are formed in the epitaxial layer 204 beside the trench 208. Two source regions 220 of the first conductivity type are respectively formed in the well regions 218 beside the trench 208. A dielectric layer 222 is formed on the epitaxial layer 204. At least two openings 224 are formed to penetrate through the dielectric layer 222 and the source regions 220 and extend into a portion of the well regions 218. Two doped regions 226 of the second conductivity type are respectively formed in the well regions 218 around bottoms of the openings 224. Two contact plugs 228 are formed in the openings 224. A conductive layer 230 is formed on the dielectric layer 222, wherein the conductive layer 230 is electrically connected to the source regions 220 via the contact plugs 228. A cover 232 is formed on the conductive layer 230. The materials and forming methods of these components have been described in the first embodiment, and the details are not iterated herein.

The semiconductor structure of the invention is explained with reference to FIG. 2E. As shown in FIG. 2E, the semiconductor structure 200 includes a substrate 202 of a first conductivity type, an epitaxial layer 204 of the first conductivity type, insulating layers 210a and 214, a silicon-containing layer 212a, a conductive layer 216, two well regions 218 of a second conductivity type and two source regions 220 of the first conductivity type. The epitaxial layer 204 is disposed on the substrate 202 and has at least one trench 208 therein, wherein the trench 208 has a straight sidewall. The insulating layer 210a covers a surface of the lower portion of the trench 208. The silicon-containing layer 212a is disposed in the lower portion 208a of the trench 208 and has a plurality of air gaps 213 and air cracks 215 therein. The insulating layer 214 is disposed between the conductive layer 216 and the epitaxial layer 204 and between the conductive layer 216 and the silicon-containing layer 212a. Besides, an air space 217 is present between the silicon-containing layer 212a and the insulating layer 214 and between the silicon containing layer 212a and the insulating layer 210a.

In addition, the insulating layer 210a and the silicon-containing layer 212a include different materials. Specifically, the insulating layer 210a is made of silicon oxide while the silicon-containing layer 212a is made of amorphous silicon. The conductive layer 216 is disposed in the upper portion 208b of the trench 208. The well regions 218 are disposed in the epitaxial layer 204 beside the trench 208. The source regions 220 are respectively disposed in the well regions 220.

The semiconductor structure 200 further includes a dielectric layer 222, a conductive layer 230 and two doped regions 226 of the second conductivity type. The dielectric layer 222 is disposed on the epitaxial layer 204. The conductive layer 230 is disposed on the dielectric layer 222 and electrically connected to the source regions 220 via two contact plugs 228. The doped regions 226 are respectively disposed in the well regions 218 and around bottoms of the contact plugs 228.

In the semiconductor structure 200 of FIG. 2E, the insulating layer 214 is used as a gate insulating layer and the conductive layer 216 is used as a gate. It is noted that the thick silicon-containing layer 212a below the conductive layer 116 has air gaps 213 and air cracks 215 therein, and an air space 217 is further provided to around the silicon-containing layer 212a, so the gate-to-drain capacitance can be significantly reduced. Specifically, the dielectric constant of air (about 1) is much less than the dielectric constant of amorphous silicon (about 11.7), so the equivalent dielectric constant in area A can be greatly decreased, thereby significantly reducing the gate-to-drain capacitance of the trench gate MOS structure.

In the present invention, at least one air gap with small dielectric constant is present in the thick bottom below the gate. Since the equivalent dielectric constant is dominated by the small dielectric constant of air (about 1), the material of the thick bottom does not matter. In other words, the material of the thick bottom in area A can include a low-k material with a dielectric constant less than 4, a high-k material with a dielectric constant equal to or greater than 4 or a combination thereof. More specifically, the material with a dielectric constant ranging from about 2 to 12 can be applied to the air gap bottom (AGB) of the present invention. Such AGB material includes porous silica with a dielectric constant of 2, fluorinated silicon oxide (SiOF) with a dielectric constant of 3.7, silicon oxide (SiO₂) with a dielectric constant of 3.9, silicon nitride (Si₃N₄) with a dielectric constant of 7.5, silicon oxynitride (SiON) with a dielectric constant of about 7.5, amorphous silicon or polysilicon with a dielectric constant of 11.7 or a combination thereof.

More specifically, the said AGB materials can be divided into two categories in terms of their material properties. One is subjected to viscous flow but small volume changing when annealed, and such material, e.g. SiO₂, SiOF, SiN, SiON or a combination thereof, can be applied to the first embodiment. The other is subjected to obviously volume reduction when annealed, and such material, e.g. amorphous silicon, porous silica, polysilicon or a combination thereof, can be applied to the second embodiment.

### Third Embodiment

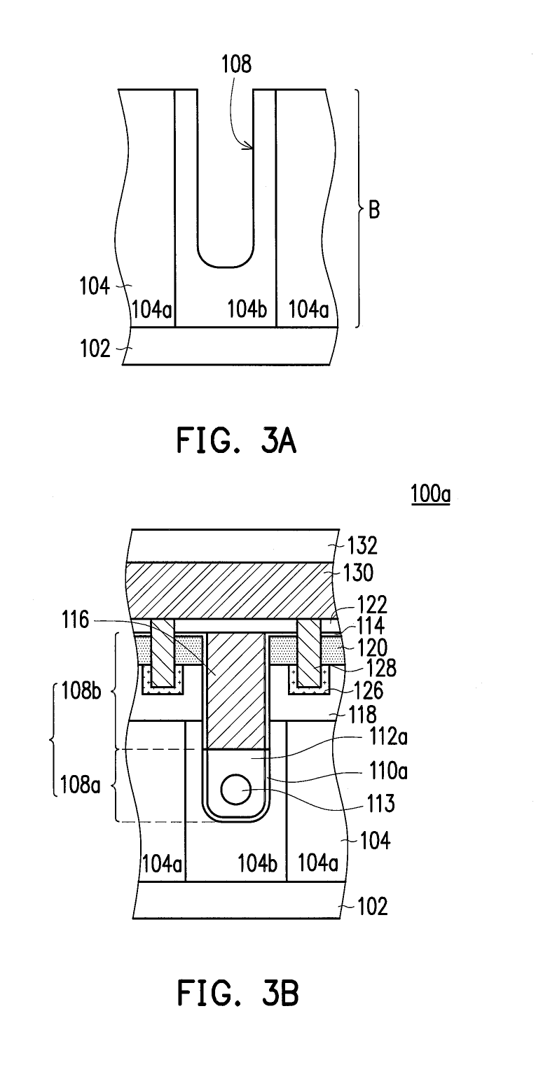

FIG. 3A to FIG. 3B are schematic cross-sectional views of a method of forming a semiconductor structure according to a third embodiment of the present invention.

The semiconductor structure 100a of the third embodiment is similar to the semiconductor structure 100 of the first embodiment, except that a plurality of pillars are further formed in the epitaxial layer in the third embodiment. The same components of the two semiconductor structures are labeled with the same reference numbers. The difference between the first and third embodiments is described in the following, and the similarities are omitted herein.

Referring to FIG. 3A, after the step of forming the epitaxial layer 104 and before the step of forming the trench 108, a plurality of pillars 104a of the second conductivity type are formed separately in the epitaxial layer 104. The pillars 104a can be P⁻ doped regions, and the forming method thereof includes performing an ion implantation process. The non-implanted regions form a plurality of pillars 104b of the first conductivity type. Specifically, the epitaxial layer 104 includes the pillars 104a and the pillars 104b alternatively arranged.

Thereafter, a trench 108 is formed in the pillars 104b of the epitaxial layer 104. In other words, the pillars 104a are separately disposed in the epitaxial layer 104, and the trench 108 is formed between two adjacent pillars 104a. Besides, the trench 108 is separated from each of the adjacent pillars 104a by a distance.

Afterwards, the steps similar to those described in FIG. 1B to FIG. 1F are performed, so as to form the semiconductor structure 100a of FIG. 3B.

It is noted that in block B of the epitaxial layer 104 (as shown in FIG. 3A), the N-type doping concentration of the N-type pillars 104b is equal to the P-type doping concentration of the P-type pillars 114a. Therefore, the block B is electrically neutral so as to reach charge balance. More specifically, in the block B of the epitaxial layer 104, a super junction structure is formed by alternately disposing the P-type dopant and the N-type dopant, so as to make the device capable of having characteristics of high breakdown voltage and low impedance.

### Fourth Embodiment

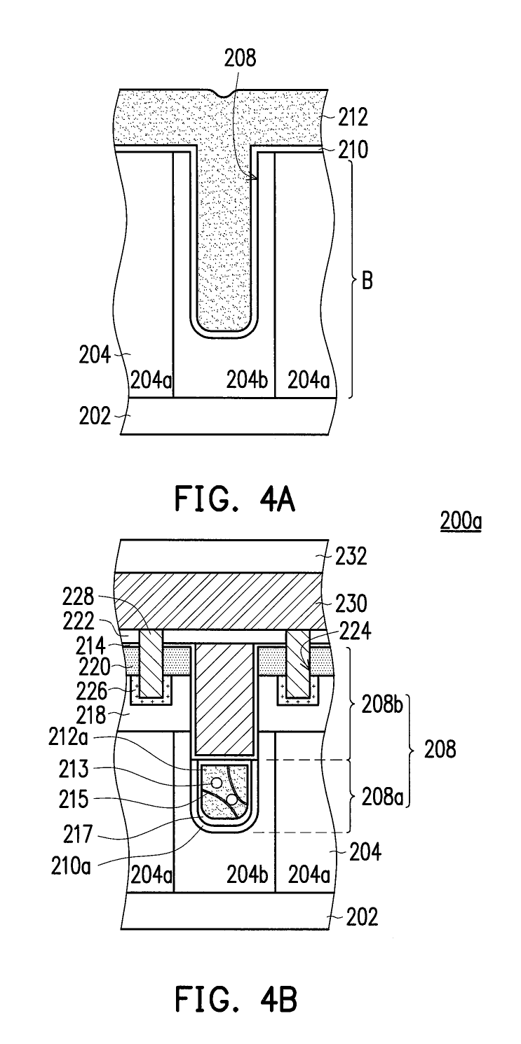

FIG. 4A to FIG. 4B are schematic cross-sectional views of a method of forming a semiconductor structure according to a fourth embodiment of the present invention.

The semiconductor structure 200a of the fourth embodiment is similar to the semiconductor structure 200 of the second embodiment, except that a plurality of pillars are further formed in the epitaxial layer in the fourth embodiment. The same components of the two semiconductor structures are labeled with the same reference numbers. The difference between the second and fourth embodiments is described in the following, and the similarities are omitted herein.

Referring to FIG. 4A, after the step of forming the epitaxial layer 204 and before the step of forming the trench 208, a plurality of pillars 204a of the second conductivity type are formed separately in the epitaxial layer 204. The pillars 204a can be P⁻ doped regions, and the forming method thereof includes performing an ion implantation process. The non-implanted regions form a plurality of pillars 204b of the first conductivity type. Specifically, the epitaxial layer 204 includes the pillars 204a and the pillars 204b alternatively arranged.

Thereafter, a trench 208 is formed in the pillars 204b of the epitaxial layer 104. In other words, the pillars 204a are separately disposed in the epitaxial layer 204, and the trench 208 is formed between two adjacent pillars 204a. Besides, the trench 208 is separated from each of the adjacent pillars 204a by a distance.

Afterwards, the steps similar to those described in FIG. 2A to FIG. 2E are performed, so as to form the semiconductor structure 200a of FIG. 4B.

It is noted that in block B of the epitaxial layer 204 (as shown in FIG. 4A), a super junction structure is formed by alternately disposing the P-type doped pillar regions and the N-type doped pillar regions, so as to make the device capable of having characteristics of high breakdown voltage and low impedance.

In summary, in the trench gate MOS structure of the invention, by providing an air gap bottom below the gate, the gate-to-drain capacitance can be effectively reduced, and the input capacitance and the switching loss can be according decreased. Furthermore, a super junction structure can be further formed in the epitaxial layer so as to make the device capable of having characteristics of high breakdown voltage and low impedance. Moreover, the method of the invention is relatively simple, and no additional photomask is needed, thereby significantly lowering cost and improving competitiveness.

The present invention has been disclosed above in the preferred embodiments, but is not limited to those. It is known to persons skilled in the art that some modifications and innovations may be made without departing from the spirit and scope of the present invention. Therefore, the scope of the present invention should be defined by the following claims.

What is claimed is:

1. A semiconductor structure, comprising:
a substrate of a first conductivity type;
an epitaxial layer of the first conductivity type, disposed on the substrate and having at least one trench therein, wherein the trench has a straight sidewall;
a first insulating layer, disposed on at least a portion of a surface of the trench;
a silicon-containing layer, disposed in a lower portion of the trench and having at least one air gap therein;
a first conductive layer, disposed in an upper portion of the trench;
two well regions of a second conductivity type, disposed in the epitaxial layer beside the trench; and
two source regions of the first conductivity type, respectively disposed in the well regions beside the trench.

2. The semiconductor structure of claim 1, wherein the first insulating layer and the silicon-containing layer comprise the same or different materials.

3. The semiconductor structure of claim 1, wherein the silicon-containing layer comprises silicon oxide, amorphous silicon, porous silica, fluorinated silicon oxide, silicon nitride, silicon oxynitride, polysilicon or a combination thereof.

4. The semiconductor structure of claim 1, wherein the first insulating layer covers an entire surface of the trench.

5. The semiconductor structure of claim 1, wherein the first insulating layer covers a surface of the lower portion of the trench.

6. The semiconductor structure of claim 5, further comprising:
a second insulating layer, disposed between the first conductive layer and the epitaxial layer and between the first conductive layer and the silicon-containing layer; and
an air space, present between the silicon-containing layer and the second insulating layer and between the silicon-containing layer and the first insulating layer.

7. The semiconductor structure of claim 1, wherein the silicon-containing layer further has a plurality of air cracks therein.

8. The semiconductor structure of claim 1, further comprising:
a plurality of pillars of the second conductivity type, separately disposed in the epitaxial layer.

9. The semiconductor structure of claim 1, further comprising:
a dielectric layer, disposed on the epitaxial layer;
a second conductive layer, disposed on the dielectric layer and electrically connected to the source regions via two contact plugs; and
two doped regions of the second conductivity type, respectively disposed in the well regions and around bottoms of the contact plugs.

10. The semiconductor structure of claim 1, wherein the first conductivity type is N-type and the second conductivity type is P-type; or the first conductivity type is P-type and the second conductivity type is N-type.

11. The method of forming a semiconductor device, comprising:
forming an epitaxial layer of a first conductivity type on a substrate of the first conductivity type;
forming at least one trench in the epitaxial layer, wherein the trench has a straight sidewall;
forming a first insulating layer at least on a portion of a surface of the trench;
forming a silicon-containing layer in a lower portion of the trench, wherein the silicon-containing layer has at least one air gap therein;
forming a first conductive layer in an upper portion of the trench;
forming two well regions of a second conductivity type in the epitaxial layer beside the trench; and
forming two source regions of the first conductivity type respectively in the well regions beside the trench.

12. The method of claim 11, wherein the steps of forming the silicon-containing layer comprises:
forming a silicon-containing material layer on the substrate filling the trench in a manner such that the air gap is simultaneously formed in the silicon-containing material layer;
annealing the silicon-containing material layer; and
removing a portion of the silicon-containing material layer.

13. The method of claim 12, wherein the silicon-containing material layer is formed by CVD, PVD or sputtering, and the annealing is performed at a temperature of about 1,000 to 1,200° C. for 10 to 180 minutes.

14. The method of claim 11, wherein the step of forming the silicon-containing layer comprises:
forming a silicon-containing material layer on the substrate filling the trench;
removing a portion of the silicon-containing material layer to form the silicon-containing layer; and
annealing the silicon-containing layer in a manner such that the air gap is simultaneously formed in the silicon-containing layer.

15. The method of claim 14, wherein the silicon-containing material layer is formed by CVD, PVD or sputtering, and the annealing is performed at a temperature of 600 to 1,000° C. for 10 to 180 minutes.

16. The method of claim 14, wherein during the annealing, an air space is simultaneously formed between the first insulating layer and the silicon-containing layer and between the second insulating layer and the silicon-containing layer, and a plurality of air cracks are simultaneously formed in the silicon-containing layer.

17. The method of claim 11, wherein the first insulating layer and the silicon-containing layer comprise the same or different materials.

18. The method of claim 11, wherein the silicon-containing layer comprises silicon oxide, amorphous silicon, porous silica, fluorinated silicon oxide, silicon nitride, silicon oxynitride, polysilicon or a combination thereof.

19. The method of claim 11, further comprising, after the step of forming the epitaxial layer and before the step of forming the trench, forming a plurality of pillars of the second conductivity type separately in the epitaxial layer.

20. The method of claim 11, further comprising:
forming a dielectric layer on the epitaxial layer;
forming at least two openings penetrating through the dielectric layer and the source regions and extending into a portion of the well regions;
forming two doped regions of the second conductivity type respectively in the well regions around bottoms of the openings;
forming two contact plugs respectively in the openings; and
forming a second conductive layer on the dielectric layer, wherein the second conductive layer is electrically connected to the source regions via the contact plugs.
